(19) United States
(12) Patent Application Publication
(10) Pub. No.: US 2026/0261097 A1
(43) Pub. Date: Sep. 3, 2026

(54) VERTICAL-CAVITY LIGHT-EMITTING ELEMENT

(71) Applicant: Stanley Electric Co., Ltd., Meguro-ku, Tokyo (JP)

(72) Inventor: Masaru KURAMOTO, Tokyo (JP)

(73) Assignee: Stanley Electric Co., Ltd., Meguro-ku, Tokyo (JP)

(21) Appl. No.: 19/491,210

(22) PCT Filed: Jun. 3, 2024
(86) PCT No.: PCT/JP2024/020134

§ 371 Date: Dec. 8, 2025

(30) Foreign Application Priority Data
Jun. 9, 2023 (JP) 2023-095409

(51) Int. Cl. H01S 5/30; H01S 5/042; H01S 5/183

(52) U.S. Cl. CPC H01S 5/305; H01S 5/04253; H01S 5/04254; H01S 5/18308; H01S 5/18361

(57) ABSTRACT

A vertical-cavity light-emitting element includes a substrate, first and second multilayer reflectors, a semiconductor structure, and a metal oxide film. The first multilayer reflector is on the substrate. The semiconductor structure includes a first semiconductor layer of one conductivity type, a light-emitting layer, and a second semiconductor layer of opposite conductivity type. The metal oxide film is translucent and formed on the second semiconductor layer, covering a central region and partially extending to a peripheral edge, where it is insulated. The metal oxide film is electrically connected only at the central region. The second multilayer reflector covers this region, forming a resonator with the first multilayer reflector.

### TECHNICAL FIELD

The present invention relates to a vertical-cavity light-emitting element.

### BACKGROUND ART

A vertical-cavity light-emitting element is known as one of the semiconductor lasers. For example, Patent Document 1 discloses a vertical-cavity surface emitting laser (VCSEL) including a semiconductor structure layer that includes an n-type semiconductor layer, a light-emitting layer, and a p-type semiconductor layer and have a protruding portion formed on an upper surface of the p-type semiconductor layer, an insulating layer formed on the upper surface of the p-type semiconductor layer, and a transmissive electrode layer that includes the insulating layer and is formed on the upper surface of the p-type semiconductor layer.

### CITED DOCUMENTS

### Patent Literature

Patent Document 1: JP-A 2021-197437

### DISCLOSURE OF THE INVENTION

### Problems To Be Solved By The Invention

In the vertical-cavity surface emitting laser disclosed in Patent Document 1, for example, a threshold current increases in association with a long period of current application, which may reduce an output of an emitted light. As a countermeasure for this, for example, suppression of the increase of the threshold current is attempted using hydrogen that has been injected into the p-type semiconductor layer. However, the flow of the current may be excessively suppressed depending on a hydrogen concentration in the p-type semiconductor layer, which may develop a problem of a reduced light-emitting area of the vertical-cavity surface emitting laser.

The present invention has been made in consideration of the above-described point and an object of which is to provide a vertical-cavity light-emitting element that allows for avoiding reduction of a light-emitting area while avoiding reduction of an optical output.

### Solutions To The Problems

A vertical-cavity light-emitting element according to the present invention includes a substrate, a first multilayer reflector, a semiconductor structure layer, a metal oxide film, and a second multilayer reflector. The first multilayer reflector is formed on the substrate. The semiconductor structure layer includes a first semiconductor layer having a first conductivity type formed on the first multilayer reflector, a light-emitting layer formed on the first semiconductor layer, a second semiconductor layer formed on the light-emitting layer and having a second conductivity type opposite of the first conductivity type. The metal oxide film has a translucency that is formed on the second semiconductor layer, covers one region at a center of an upper surface of the second semiconductor layer, is electrically connected to the second semiconductor layer in the one region, is partially formed on a peripheral edge region on a peripheral edge of the one region, and is insulated from a surface of the second semiconductor layer in the peripheral edge region. The second multilayer reflector is formed to cover the one region on the semiconductor structure layer and constituting a resonator between the first multilayer reflector and the second multilayer reflector.

### BRIEF DESCRIPTION OF THE DRAWINGS

FIG. 1 is a perspective view of a vertical-cavity surface emitting laser according to Example 1.

FIG. 2 is a top view of the vertical-cavity surface emitting laser according to Example 1.

FIG. 3 is a cross-sectional view of the vertical-cavity surface emitting laser according to Example 1.

FIG. 4 is a cross-sectional view of a vertical-cavity surface emitting laser as a conventional example.

FIG. 5 is a top view of a vertical-cavity surface emitting laser according to a modification of Example 1.

FIG. 6 is a top view of a vertical-cavity surface emitting laser according to a modification of Example 1.

FIG. 7 is a top view of a vertical-cavity surface emitting laser according to a modification of Example 1.

FIG. 8 is a cross-sectional view of a vertical-cavity surface emitting laser according to Example 2.

### DESCRIPTION OF PREFERRED EMBODIMENTS

The following specifically describes Examples of the present invention with reference to the drawings. Note that the same components are attached with the same reference numerals in the drawings, and descriptions of overlapping components are omitted.

### Example 1

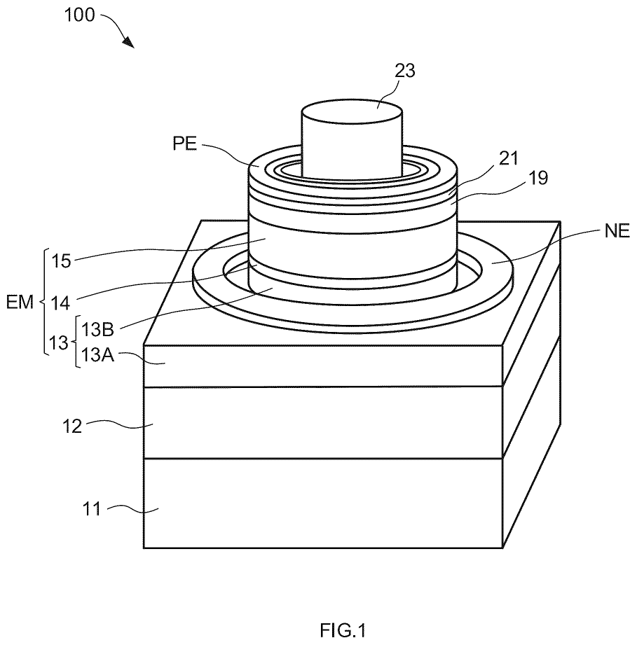

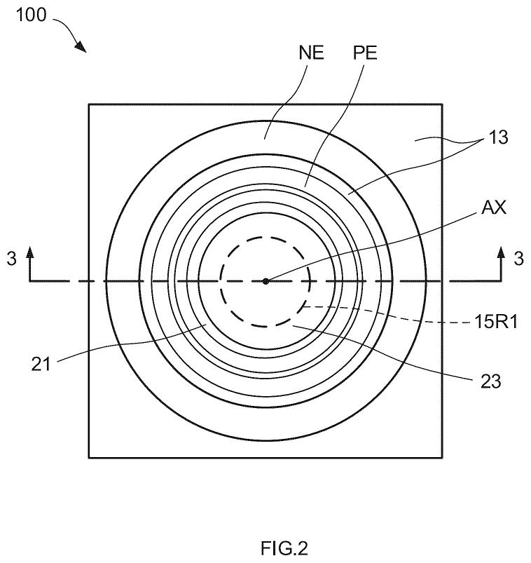

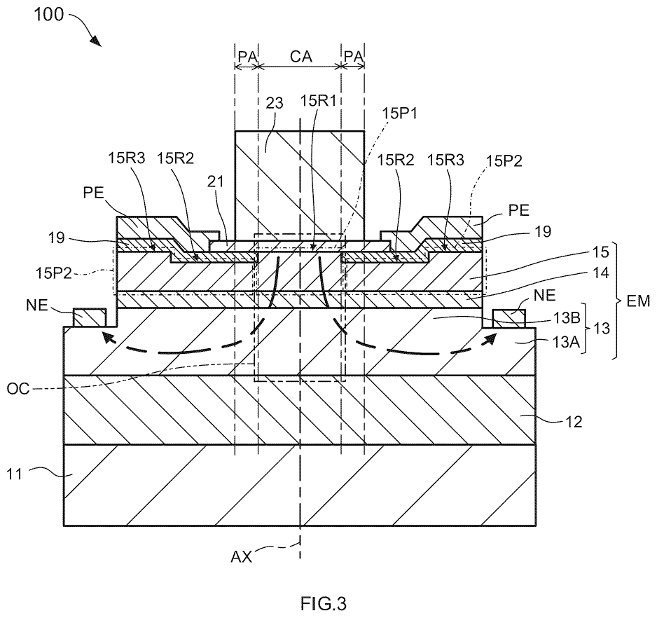

Using FIG. 1 to FIG. 3, a configuration of a vertical-cavity surface emitting laser 100 (hereinafter referred to as a surface emitting laser 100) according to Example 1 will be described. FIG. 1 is a perspective view of the surface emitting laser 100. FIG. 2 is a top view of the surface emitting laser 100, and FIG. 3 is a cross-sectional view taken along the line 3-3 of the surface emitting laser 100 illustrated in FIG. 2. Note that, in FIG. 3, an up-down direction in the drawing is a height direction of the surface emitting laser 100.

A substrate 11 is a flat plate-shaped transparent substrate with an upper surface in a rectangular shape. The substrate 11 is a growth substrate that allows growth of a semiconductor crystal on the upper surface thereof. The substrate 11 is, for example, made of a material that has translucency to a light having a blue-color wavelength, such as undoped gallium nitride (GaN). In the following description, an axis passing through the center of the upper surface of the substrate 11 and perpendicular to the upper surface is described as a center axis AX.

A first multilayer reflector 12 is a semiconductor multilayer reflector formed from a semiconductor layer grown on the substrate 11. The first multilayer reflector 12 is, what is called, a Distributed Bragg Reflector (DBR) formed by alternately laminating high refractive-index semiconductor films having a relatively high refractive index and low refractive-index semiconductor films having a refractive index lower than that of the high refractive-index semiconductor film on the upper surface of the substrate 11.

The first multilayer reflector 12 is, for example, formed by laminating 42 pairs of the high refractive-index semiconductor films made of GaN and the low refractive-index semiconductor films made of indium aluminum nitride (AlInN) on the upper surface of the substrate 11. The first multilayer reflector 12 has reflectivity to a light in a blue-color wavelength band by having such a configuration. Note that a buffer layer (not illustrated) made of GaN is disposed between the substrate 11 and the first multilayer reflector 12.

A semiconductor structure layer EM is a laminated structure formed from a plurality of semiconductor layers formed on the first multilayer reflector 12. The semiconductor structure layer EM has an n-type semiconductor layer 13 formed on the first multilayer reflector 12, a light-emitting layer 14 formed on the n-type semiconductor layer 13, and a p-type semiconductor layer 15 formed on the light-emitting layer 14.

The following describes respective structures of the n-type semiconductor layer 13, the light-emitting layer 14, and the p-type semiconductor layer 15 constituting the semiconductor structure layer EM.

The n-type semiconductor layer 13 as a first semiconductor layer that has a first conductivity type is a semiconductor layer formed over an upper surface of the first multilayer reflector 12. The n-type semiconductor layer 13 is made of GaN, and doped with silicon (Si) as n-type impurities.

The n-type semiconductor layer 13 has, what is called, a mesa-shaped structure (see FIG. 1 and FIG. 3) constituted of a flat plate-shaped lower portion 13A and a column-shaped upper portion 13B that protrudes upward along the center axis AX from the center of the lower portion 13A.

The light-emitting layer 14 is formed over the upper portion 13B of the n-type semiconductor layer 13, and is a semiconductor layer having a quantum well structure in which a well layer made of InGaN and a barrier layer made of GaN are mutually laminated. The light-emitting layer 14 is formed such that its luminescence center is positioned on the center axis AX. The light-emitting layer 14 emits a blue light having, for example, a peak wavelength of 450 nm.

The p-type semiconductor layer 15 as a second semiconductor layer having a second conductivity type is a semiconductor layer formed over an upper surface of the light-emitting layer 14. The p-type semiconductor layer 15 is made of GaN, and is doped with magnesium (Mg) as p-type impurities.

The p-type semiconductor layer 15 has a first region 15R1 that is a region having an annular shape and passing through the center axis AX, and a circular ring-shaped second region 15R2 that is a region of a peripheral edge of the first region 15R1 and recessed downward relative to the first region 15R1 on the upper surface (see FIG. 3). In other words, the p-type semiconductor layer 15 has a protruding portion that protrudes upward in the center of the upper surface.

The p-type semiconductor layer 15 has a third region 15R3 that is a region of a peripheral edge of the second region 15R2 and protrudes to an upper side with respect to the second region 15R2, on the upper surface. That is, the p-type semiconductor layer 15 has a recessed portion having the second region 15R2 as a bottom surface on the upper surface.

In the p-type semiconductor layer 15, the second region 15R2 is a region in which the p-type impurities (Mg) doped in the p-type semiconductor layer 15 are electrically deactivated. The second region 15R2 is, for example, formed by dry-etching the upper surface of the flat plate-shaped p-type semiconductor layer so as to keep the regions corresponding to the first region 15R1 and the third region 15R3.

In the second region 15R2, the p-type impurities are deactivated by receiving damages from the dry-etching. Specifically, the p-type impurities are in the state of being electrically activated by being disposed at the lattice position of the crystal of the p-type semiconductor layer 15 when the p-type semiconductor layer is formed.

In the second region 15R2, this is in the state where the p-type impurities are off of the lattice position of the crystal of the p-type semiconductor layer 15 after undergoing the dry-etching, or the state where the p-type impurities no longer function as acceptor ions due to defects generated by the dry-etching, that is, the state of electrically inactive. In other words, the second region 15R2 is a region where the p-type impurities are less likely to generate carriers.

Accordingly, the second region 15R2 functions as a high resistance region having an electrical resistance higher than that of the first region 15R1, on the upper surface of the p-type semiconductor layer 15. On the other hand, the first region 15R1 and the third region 15R3, which are the regions without the dry-etching, that is, the regions where the p-type impurities are electrically activated, function as low resistance regions having an electrical resistance lower than that of the second region 15R2.

In the surface emitting laser 100, compared with a first portion 15P1 that is a portion along the first region 15R1 of the p-type semiconductor layer 15, a second portion 15P2 that is a portion of a peripheral edge of the first portion 15P1 and also a portion along the second region 15R2 and the third region 15R3 has a high hydrogen concentration.

Specifically, in the p-type semiconductor layer 15, the hydrogen concentration in the second portion 15P2 is equal to or more than twice as high as the hydrogen concentration in the first portion 15P1. For example, the hydrogen concentration in the first portion 15P1 is 1×10¹⁸/cm³, and the hydrogen concentration in the second portion 15P2 is 2×10¹⁸/cm^{3.}

An insulating layer 19 is a transparent coating layer having an electrical insulating property formed to continuously cover the second region 15R2 and the third region 15R3 on the upper surface of the p-type semiconductor layer 15. In other words, the insulating layer 19 is formed on the upper surface of the p-type semiconductor layer 15 so as to expose only the first region 15R1 of the upper surface of the p-type semiconductor layer 15.

The insulating layer 19 is formed to have an inclined surface that inclines downward from the third region 15R3 to the second region 15R2 on the upper surface of the p-type semiconductor layer 15. The insulating layer 19 is made of a material with a refractive index lower than that of the p-type semiconductor layer 15, such as silicon dioxide (SiO₂).

A conductive film 21 is a transparent metal oxide film formed to extend to the middle of the second region 15R2 from the first region 15R1 while covering the first region 15R1 described above in plan view viewing the p-type semiconductor layer 15 from above. In other words, the conductive film 21 is formed in the aspect of not reaching an outer edge of the upper surface of the p-type semiconductor layer 15 while covering the first region 15R1.

The conductive film 21 is electrically connected to the p-type semiconductor layer 15 in the first region 15R1, and is electrically insulated from the second region 15R2 and the third region 15R3 by the insulating layer 19. That is, when a current flows in the conductive film 21, a significant part of the current flows into the p-type semiconductor layer 15 via the first region 15R1.

The conductive film 21 is, for example, made of a metal oxide having translucency to the blue light emitted from the light-emitting layer 14, such as indium tin oxide (ITO) or indium zinc oxide (IZO). While it depends on absorptivity or the like of the light emitted from the light-emitting layer 14, the conductive film 21 has a film thickness of, preferably 10 nm to 100 nm, and more preferably 10 nm to 50 nm.

During the manufacture of the surface emitting laser 100, for example, after a metal oxide film made of ITO is formed over the upper surface of the p-type semiconductor layer 15, the formed metal oxide film is removed from the outer edge of the third region 15R3 to the middle of the second region by etching or plasma cleaning, and thus, the conductive film 21 is formed.

A p-electrode PE is a metal electrode having an upper surface in a loop shape, formed to cover the outer edge of the conductive film 21 along the outer edge of the upper surface of the p-type semiconductor layer 15 on the insulating layer 19, and electrically connected to the conductive film 21. The p-electrode PE is made of, for example, nickel (Ni) and gold (Au) formed in this order.

An n-electrode NE is a metal electrode having an upper surface in a loop shape, disposed on an upper surface of the lower portion 13A of the n-type semiconductor layer 13, and electrically connected to the n-type semiconductor layer 13. The n-electrode NE is formed to be separated from the upper portion 13B while surrounding the upper portion 13B of the n-type semiconductor layer 13 in plan view viewing the surface emitting laser 100 from above. The n-electrode NE is, for example, made of titanium (Ti) and aluminum (Al) laminated in this order on the upper surface of the lower portion 13A.

A second multilayer reflector 23 is a column-shaped dielectric multilayer reflector formed from a dielectric layer formed on the upper surface of the conductive film 21. The second multilayer reflector 23 is formed to cover the first region 15R1 while being separated from the p-electrode PE in plan view viewing the surface emitting laser 100 from above.

The second multilayer reflector 23 is, what is called, a distributed bragg reflector (DBR) formed by alternately laminating high refractive-index dielectric films having a relatively high refractive index and low refractive-index dielectric films having a refractive index lower than that of the high refractive-index dielectric film on the upper surface of the conductive film 21.

The second multilayer reflector 23 is, for example, formed by laminating 10.5 pairs of the high refractive-index dielectric films made of niobium pentoxide (Nb2O5) and the low refractive-index dielectric films made of SiO₂ on the upper surface of the conductive film 21. The second multilayer reflector 23 has reflectivity to the blue light emitted from the light-emitting layer 14 by having such a configuration.

Note that a transparent dielectric layer (not illustrated) with an upper surface in a circular shape is formed between the second multilayer reflector 23 and the conductive film 21. The dielectric layer is made of, for example, Nb₂O₅, tantalum pentoxide (Ta₂O₅), zirconium oxide (ZrO₂), titanium oxide (TiO₂), or hafnium oxide (HfO₂).

In the surface emitting laser 100, the second multilayer reflector 23 has a lower surface opposed to the upper surface of the first multilayer reflector 12 with the dielectric layer, the conductive film 21, and the semiconductor structure layer EM described above interposed therebetween. Thus, the first multilayer reflector 12 and the second multilayer reflector 23 constitute a resonator OC with a direction perpendicular to the semiconductor structure layer EM (a direction perpendicular to the substrate 11) as a resonator length direction between the first multilayer reflector 12 and the second multilayer reflector 23.

In the surface emitting laser 100, the reflectivity of the first multilayer reflector 12 to the blue light is slightly lower than the reflectivity of the second multilayer reflector 23 to the blue light. Accordingly, the blue light resonated in the resonator OC partly transmits through the first multilayer reflector 12 and the substrate 11 and is taken out to the outside. That is, the light that has been resonated between the first multilayer reflector 12 and the second multilayer reflector 23 is emitted downward in FIG. 3.

Note that the substrate 11 has a lower surface on which an anti-reflection film (not illustrated) formed by laminating Nb₂O₅ and SiO₂ is formed. The anti-reflection film is, what is called, an AR coating that inhibits the blue light emitted from the substrate 11 from being reflected upward in FIG. 3 by an interface between the substrate 11 and the outside.

Here, a description will be given of an operation of the surface emitting laser 100 and the optical characteristics. When a voltage is applied to the n-electrode NE and the p-electrode PE described above and a current flows between the n-electrode NE and the p-electrode PE, the current flows in the light-emitting layer 14 of the semiconductor structure layer EM as illustrated by the arrow with the bold one dot chain line in FIG. 3. When a threshold current that is a predetermined current value is reached, an intensity of the blue light emitted from the light-emitting layer 14 rapidly increases.

The blue light emitted from the light-emitting layer 14 after reaching the threshold current is repeatedly reflected between the first multilayer reflector 12 and the second multilayer reflector 23, that is, in the resonator OC to reach the resonant state (that is, performs laser oscillation).

At this time, a significant part of the current flowing from the p-electrode PE to the conductive film 21 flows to the n-electrode NE via the first region 15R1, which is the low resistance region, in the p-type semiconductor layer 15. Accordingly, in the surface emitting laser 100, the current is supplied to the light-emitting layer 14 via the first region 15R1, and the blue light is emitted along the center axis AX from the first region 15R1.

That is, in the surface emitting laser 100, the protruding portion at the center of the p-type semiconductor layer 15 formed by the first region 15R1 and the second region 15R2, and the insulating layer 19 formed on the second region 15R2 function as current narrowing portions that restrict a supply range of the current so as to stop the current from spreading any further.

Accordingly, when the current is applied from the p-electrode PE to the n-electrode NE, the significant part of the current flowing in the conductive film 21 flows to the n-type semiconductor layer 13 via the first portion 15P1 of the p-type semiconductor layer 15 but the current hardly flows to the second portion 15P2.

In the surface emitting laser 100, an equivalent refractive index that is an average refractive index in a thickness direction between the first multilayer reflector 12 and the second multilayer reflector 23 is different between a column-shaped central region CA including the first region 15R1 of the p-type semiconductor layer 15 and a pipe-shaped peripheral region PA around the central region CA.

Specifically, the refractive index of the insulating layer 19 in the peripheral region PA is lower than the refractive index of the above-described protruding portion (the p-type semiconductor layer 15) in the central region CA, and therefore, the equivalent refractive index in the central region CA is greater than the equivalent refractive index in the peripheral region PA.

The surface emitting laser 100 having such a configuration suppresses the optical loss caused by a standing wave inside the central region CA being diffused (radiated) in the peripheral region PA. That is, a large amount of the light remains in the central region CA, and the laser light is taken outside in that state.

Accordingly, a large amount of the light emitted from the light-emitting layer 14 concentrates in the central region CA, and thus, a laser light with a high output power and high density can be generated and emitted. That is, a transverse mode of the laser light emitted from the surface emitting laser 100 (an intensity distribution on a transverse surface of a laser beam) can be stabilized.

### Suppression of Reduction of Light-emitting Area in Surface Emitting Laser

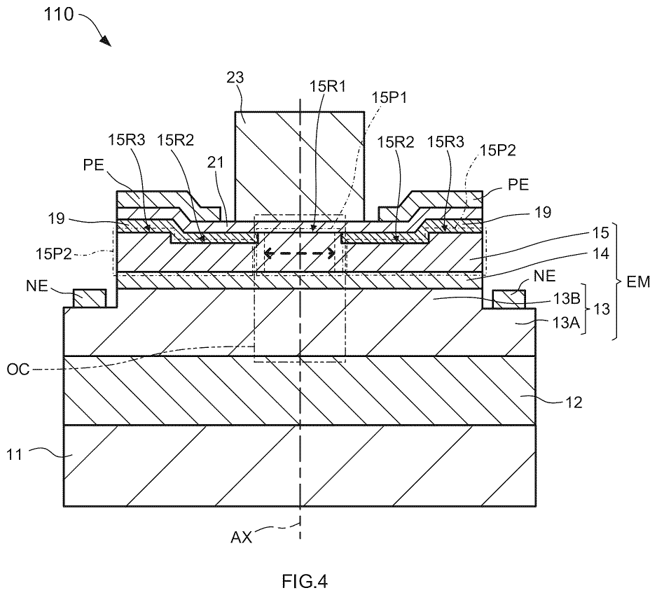

The following describes suppression of reduction of a light-emitting area in the surface emitting laser 100 according to the Example using FIG. 3 and FIG. 4. FIG. 4 is a cross-sectional view of a surface emitting laser 110 as a conventional example. The surface emitting laser 110 is different from the surface emitting laser 100 in that the conductive film 21 is formed over the upper surface of the p-type semiconductor layer 15, and is the rest is the same as the surface emitting laser 100.

As described above, in the surface emitting laser 100, the hydrogen concentration in the second portion 15P2 of the p-type semiconductor layer 15 is higher than the hydrogen concentration in the first portion 15P1. Here, a description will be given of one example of a method of generating a hydrogen concentration difference between the first portion 15P1 and the second portion 15P2 of the p-type semiconductor layer 15 during the manufacture of the surface emitting laser 100.

During the manufacture of the surface emitting laser 100, the conductive film 21 is gradually formed while incorporating hydrogen from the atmosphere, for example by sputter-depositing it on the p-type semiconductor layer 15 at a deposition rate of 2 nm/min and at 25° C. This makes the hydrogen concentration in the conductive film 21, for example, approximately 1×10²¹/cm³.

Thereafter, an electrode annealing process (600° C., five minutes) is performed in order to decrease a contact resistance between the conductive film 21 and a surface of the p-type semiconductor layer 15, which moves the hydrogen included in the conductive film 21 into the p-type semiconductor layer 15 such that the hydrogen remains in the first portion 15P1 and the second portion 15P2 of the p-type semiconductor layer 15 at an approximately similar concentration to one another.

Note that while the movement of the hydrogen included in the conductive film 21 is assumed to be blocked by the insulating layer 19 between the conductive film 21 and the second portion 15P2, in practice, the hydrogen passes through the insulating layer 19 and moves to the second portion 15P2. While the reason is not necessarily apparent, it is estimated to be related to the insulating layer 19 being a polycrystal or amorphous and not having a densely packed solid structure, such as a single crystal, or fine pinholes present in the insulating layer 19.

Thereafter, a current is applied between the n-electrode NE and the p-electrode PE after the manufacture of the surface emitting laser 100 is completed. At this time, the insulating layer 19 is formed on the second region 15R2 and the third region 15R3, and therefore, a significant part of the current that flows from the p-electrode PE to the n-electrode NE via the conductive film 21 flows via the first portion 15P1, but hardly flows to the second portion 15P2.

Accordingly, the hydrogen remaining in the first portion 15P1 exits to the n-type semiconductor layer 13 simultaneously with the current application, whereas a significant part of the hydrogen remaining in the second portion 15P2 does not exit even though the current is applied, and therefore, remains in the second portion 15P2.

Therefore, the hydrogen concentration in the second portion 15P2 becomes higher than the hydrogen concentration in the first portion 15P1.

Thus, making the hydrogen concentration in the second portion 15P2 higher than the hydrogen concentration in the first portion 15P1 spreads the hydrogen in the p-type semiconductor layer 15 in accordance with the concentration gradient from the high concentration region to the low region, that is, from the second portion 15P2 to the first portion 15P1.

For example, when the current is applied to the surface emitting laser 100 over a long period, there may occur a phenomenon in which the current whose significant part flowing only in the first portion 15P1 at the operation start of the surface emitting laser 100 flows also to the second portion 15P2 while flowing in the first portion 15P1. That is, a phenomenon in which a current path of the current flowing in the p-type semiconductor layer 15 spreads due to a long period of current application may occur. When such a phenomenon occurs, the optical loss in the resonator OC increases, which may increase the threshold current required for laser oscillation.

At this time, when the hydrogen concentration in the second portion 15P2 is higher than the hydrogen concentration in the first portion 15P1, the hydrogen diffusing power of diffusion from the second portion 15P2 toward the first portion 15P1 allows for suppressing the phenomenon of the current path spread in the p-type semiconductor layer 15 described above.

Accordingly, for example, even when the surface emitting laser 100 is applied over a long period to a device, such as a display or a headlamp, used in a constant current drive condition, reduction in intensity of the emitted light due to the increase of the threshold current is avoidable.

However, when the electrode annealing and the current application described above are performed in the state where the conductive film 21 is formed over the upper surface of the p-type semiconductor layer 15 during the manufacture of the surface emitting laser, there may occur a phenomenon in which the difference between the hydrogen concentration in the first portion 15P1 and the hydrogen concentration in the second portion 15P2 becomes excessively large. For example, in the case of the surface emitting laser 110 according to the conventional example illustrated in FIG. 4, the hydrogen concentration in the second portion 15P2 can be five times or more the hydrogen concentration of the first portion 15P1.

Thus, when the hydrogen concentration difference between the first portion 15P1 and the second portion 15P2 is excessively large, the hydrogen in the second portion 15P2 is excessively diffused in the first portion 15P1, and thus, a diameter (the thick wavy line in FIG. 4) of the current that passes through the first portion 15P1 becomes narrower than a diameter of the first region 15R1.

When the diameter of the current that flows in the first portion 15P1 is narrowed, the diameter of the current injected into the light-emitting layer 14 is also narrowed, and there may be a phenomenon in which the area of the light emitted from the surface emitting laser 110, that is, the light-emitting area reduces.

In the surface emitting laser 100 according to the Example, the conductive film 21 is formed in the aspect of not reaching the outer edge of the upper surface of the p-type semiconductor layer 15 as illustrated in FIG. 3. That is, the conductive film 21 on the second portion 15P2 in the surface emitting laser 100 according to the Example has a volume smaller than a volume of the conductive film 21 on the second portion 15P2 in the surface emitting laser 110 according to the conventional example.

Accordingly, with the surface emitting laser 100 according to the Example, when the electrode annealing of the conductive film 21 is performed during the manufacture of the surface emitting laser 100 as described above, only the hydrogen included in the conductive film 21 formed on the second portion 15P2 flows in the second portion 15P2. Therefore, the average hydrogen concentration in the second portion 15P2 in the surface emitting laser 100 is small compared with the average hydrogen concentration in the second portion 15P2 in the surface emitting laser 110.

That is, with the surface emitting laser 100 according to the Example, forming the conductive film 21 in the aspect of not reaching the outer edge of the upper surface of the p-type semiconductor layer 15 reduces the hydrogen concentration in the second portion 15P2, which allows for controlling the hydrogen concentration difference between the first portion 15P1 and the second portion 15P2 not to be excessively large.

Note that, in order to avoid reduction in intensity of the emitted light due to the increase of the threshold current as described above, the hydrogen concentration in the second portion 15P2 is preferred to be at least double the hydrogen concentration in the first portion 15P1.

In order to avoid narrowing of the diameter of the current flowing in the first portion 15P1, the hydrogen concentration in the second portion 15P2 is preferred to be less than five times the hydrogen concentration in the first portion 15P1. Accordingly, the hydrogen concentration in the second portion 15P2 is preferred to be double or more and less than five times the hydrogen concentration in the first portion 15P1.

Accordingly, with the surface emitting laser 100 according to the Example, the conductive film 21 is formed in the aspect of not reaching the outer edge of the upper surface of the p-type semiconductor layer 15, which allows for avoiding a reduced light-emitting area while avoiding a reduced optical output.

### Modification 1

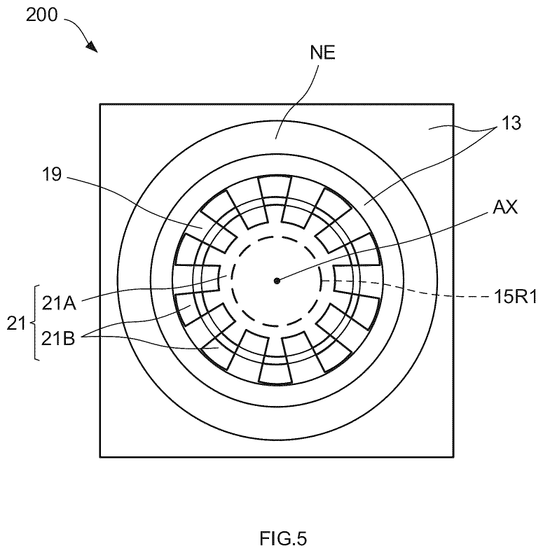

Next, a description will be given of Modification 1 of the surface emitting laser 100 in Example 1 using FIG. 5. FIG. 5 is a top view of a surface emitting laser 200 according to Modification 1. The surface emitting laser 200 is different from Example 1 in the formation aspect of the conductive film 21, and the rest is similar to Example 1. Note that, in FIG. 5, the p-electrode PE and the second multilayer reflector 23 are omitted from illustration in order to avoid complication of the drawing.

In the surface emitting laser 200, the conductive film 21 is constituted of a central portion 21A formed to cover the first region 15R1 on the upper surface of the p-type semiconductor layer 15, and an extending portion 21B that radially extends from the central portion 21A and reaches the outer edge of the third region 15R3 as illustrated in FIG. 5. That is, in the surface emitting laser 200 of the Modification, the conductive film 21 is formed to expose the insulating layer 19 from between the extending portions 21B adjacent to one another.

Even in the case where the conductive film 21 is thus formed, the volume of the conductive film 21 formed on the second portion 15P2 is smaller than the case where the conductive film 21 is formed over the upper surface of the p-type semiconductor layer 15. Accordingly, during the manufacture of the surface emitting laser 200, the hydrogen concentration difference between the first portion 15P1 and the second portion 15P2 can be controlled not to be excessively large.

Accordingly, with the surface emitting laser 200 in the Modification, the conductive film 21 is partially formed on the second portion 15P2 of the p-type semiconductor layer 15, which allows for avoiding a reduced light-emitting area while avoiding a reduced optical output.

Note that, in the Modification, the conductive film 21 is formed to have an inclined surface along the inclined surface of the insulating layer 19 described above. The conductive film 21 is thus formed, which allows for expectation of improved durability against a crack or the like in a long-term use compared with the case where the conductive film 21 is simply formed into a flat plate shape.

### Modification 2

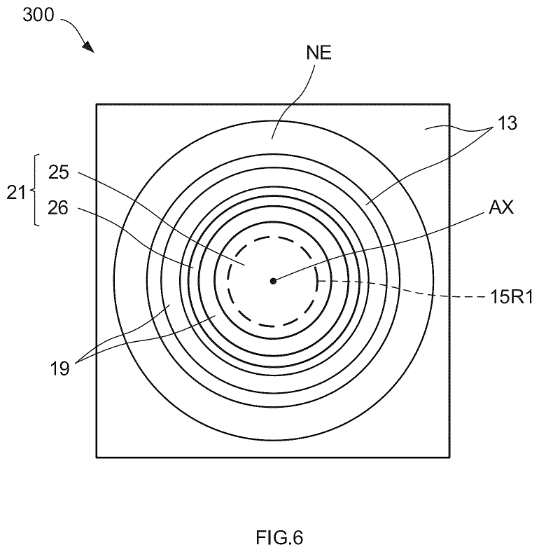

Next, a description will be given of Modification 2 of the surface emitting laser 100 in Example 1 using FIG. 6. FIG. 6 is a top view of a surface emitting laser 300 according to Modification 2. The surface emitting laser 300 is different from Example 1 in the formation aspect of the conductive film 21, and the rest is similar to Example 1. Note that, also in FIG. 6, the p-electrode PE and the second multilayer reflector 23 are omitted from illustration in order to avoid complication of the drawing.

In the surface emitting laser 300, the conductive film 21 is constituted of a first conductive film 25 as a first metal oxide film formed to cover the first region 15R1 on the upper surface of the p-type semiconductor layer 15, and a second conductive film 26 as a second metal oxide film formed to be separated from the first conductive film 25 on the second region 15R2 as illustrated in FIG. 6.

Even when the conductive film 21 is thus formed, the volume of the conductive film 21 formed on the second portion 15P2 is smaller than the case where the conductive film 21 is formed over the upper surface of the p-type semiconductor layer 15. Accordingly, during the manufacture of the surface emitting laser 300, the hydrogen concentration difference between the first portion 15P1 and the second portion 15P2 can be controlled not to be excessively large.

Accordingly, with the surface emitting laser 300 according to the Modification, the conductive film 21 is partially formed on the second portion 15P2 of the p-type semiconductor layer 15, which allows for avoiding a reduced light-emitting area while avoiding a reduced optical output.

### Modification 3

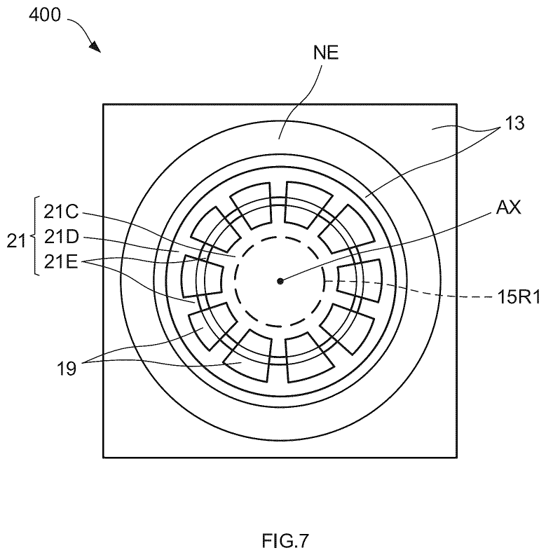

Next, a description will be given of Modification 3 of the surface emitting laser 100 in Example 1 using FIG. 7. FIG. 7 is a top view of a surface emitting laser 400 according to Modification 3. The surface emitting laser 400 is different from Example 1 in the formation aspect of the conductive film 21, and the rest is similar to Example 1. Note that, also in FIG. 7, the p-electrode PE and the second multilayer reflector 23 are omitted from illustration in order to avoid complication of the drawing.

In the surface emitting laser 400, the conductive film 21 is constituted of a central portion 21C formed to cover the first region 15R1 on the upper surface of the p-type semiconductor layer 15, a loop-shaped outer periphery portion 21D that surrounds the central portion 21C and is formed along the outer edge of the third region 15R3, and a connecting portion 21E that radially extends from the central portion 21C and connects the central portion 21C to the outer periphery portion 21D as illustrated in FIG. 7.

Even in the case where the conductive film 21 is thus formed, the volume of the conductive film 21 formed on the second portion 15P2 is smaller than the case where the conductive film 21 is formed over the upper surface of the p-type semiconductor layer 15. Accordingly, during the manufacture of the surface emitting laser 400, the hydrogen concentration difference between the first portion 15P1 and the second portion 15P2 can be controlled not to be excessively large.

Accordingly, with the surface emitting laser 400 according to the Modification, the conductive film 21 is partially formed on the second portion 15P2 of the p-type semiconductor layer 15, which allows for avoiding a reduced light-emitting area while avoiding a reduced optical output.

### Example 2

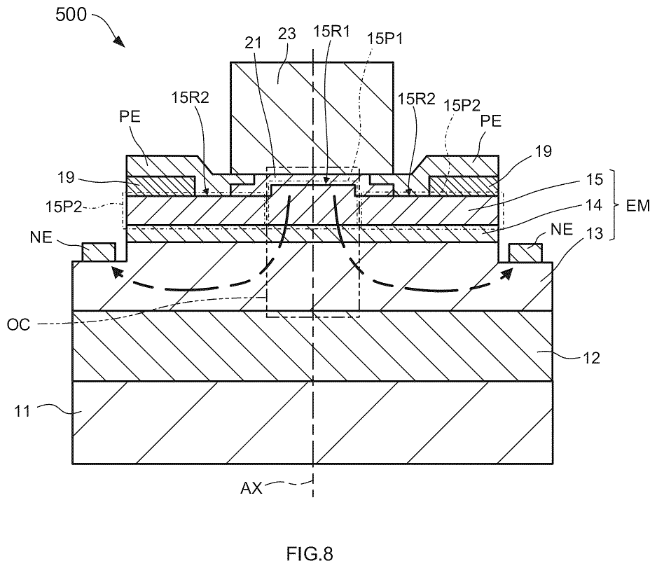

Next, a description will be given of a surface emitting laser 500 according to Example 2 using FIG. 8. FIG. 8 is a cross-sectional view of the surface emitting laser 500. The surface emitting laser 500 is different from Example 1 in the shape of the p-type semiconductor layer 15 and the formation aspects of the insulating layer 19 and the conductive film 21, and the rest is similar to Example 1.

In the surface emitting laser 500, the p-type semiconductor layer 15 has only the first region 15R1 and the second region 15R2 recessed to a lower side with respect to the first region 15R1 on the peripheral edge of the first region 15R1 on the upper surface.

That is, the second region 15R2 is formed from the outer edge of the first region 15R1 to the outer edge of the p-type semiconductor layer 15 in plan view viewing the surface emitting laser 500 from above. Accordingly, the p-type semiconductor layer 15 is constituted of the first portion 15P1 along the first region 15R1 and the second portion 15P2 along the second region 15R2.

In the surface emitting laser 500, the insulating layer 19 is formed from the outer edge of the p-type semiconductor layer 15 to the middle of the second region 15R2. The insulating layer 19 is formed to be separated from the conductive film 21 on the second region 15R2. In other words, in the surface emitting laser 500, a part of the second region 15R2 is exposed between the insulating layer 19 and the conductive film 21.

In the surface emitting laser 500, the p-electrode PE is formed to be in contact with the conductive film 21 and the part of the second region 15R2 exposed from between the insulating layer 19 and the conductive film 21 described above. As described above, since the second region 15R2 functions as a high resistance region, when a current flows from the p-electrode PE to the n-electrode NE, the current flows only in the conductive film 21, and flows into the p-type semiconductor layer 15 via the first region 15R1.

Even in the case where the p-type semiconductor layer 15 and the conductive film 21 are thus formed, the volume of the conductive film 21 formed on the second portion 15P2 is smaller than the case where the conductive film 21 is formed over the upper surface of the p-type semiconductor layer 15. Accordingly, during the manufacture of the surface emitting laser 500, the hydrogen concentration difference between the first portion 15P1 and the second portion 15P2 can be controlled not to be excessively large.

Accordingly, with the surface emitting laser 500 according to the Example, the conductive film 21 is partially formed on the second portion 15P2 of the p-type semiconductor layer 15, which allows for avoiding a reduced light-emitting area while avoiding a reduced optical output.

### DESCRIPTION OF REFERENCE SIGNS

100, 200, 300, 400, 500 Surface emitting laser
11 Substrate
12 First multilayer reflector
13 n-type semiconductor layer
14 Light-emitting layer
15 p-type semiconductor layer
19 Insulating layer
21 Conductive film
23 Second multilayer reflector
NE n-electrode
PE p-electrode

1. A vertical-cavity light-emitting element comprising:
a substrate;
a first multilayer reflector formed on the substrate;
a semiconductor structure layer including a first semiconductor layer having a first conductivity type formed on the first multilayer reflector, a light-emitting layer formed on the first semiconductor layer, a second semiconductor layer formed on the light-emitting layer and having a second conductivity type opposite of the first conductivity type;
a metal oxide film having a translucency that is formed on the second semiconductor layer, covers one region at a center of an upper surface of the second semiconductor layer, is electrically connected to the second semiconductor layer in the one region, is partially formed on a peripheral edge region on a peripheral edge of the one region, and is insulated from a surface of the second semiconductor layer in the peripheral edge region; and
a second multilayer reflector formed to cover the one region on the semiconductor structure layer and constituting a resonator between the first multilayer reflector and the second multilayer reflector.

2. The vertical-cavity light-emitting element according to claim 1, wherein
in the second semiconductor layer, a second portion along the peripheral edge has a high hydrogen concentration compared with a first portion along the one region on

3. The vertical-cavity light-emitting element according to claim 2, wherein
a hydrogen concentration in the second portion is double or more and less than five times a hydrogen concentration in the first portion.

4. The vertical-cavity light-emitting element according to claim 1, wherein
the metal oxide film is formed in an aspect of not reaching an outer edge of the peripheral edge region in plan view from a direction perpendicular to the upper surface of the second semiconductor layer.

5. The vertical-cavity light-emitting element according to claim 1, wherein
the metal oxide film includes a central portion that covers the one region and an extending portion that radially extends from the central portion, in plan view viewing a direction perpendicular to the upper surface of the second semiconductor layer.

6. The vertical-cavity light-emitting element according to claim 1, wherein
the metal oxide film is formed from a first metal oxide film that covers the one region, and a second metal oxide film formed to be separated from the first metal oxide film on the peripheral edge region in plan view from a direction perpendicular to the upper surface of the second semiconductor layer.

7. The vertical-cavity light-emitting element according to claim 6, comprising
a connecting portion that radially extends from the first metal oxide film and connects the first metal oxide film to the second metal oxide film.

8. The vertical-cavity light-emitting element according to claim 1, comprising
an insulating layer with an electrical insulating property formed on the peripheral edge region of the second semiconductor layer.

9. The vertical-cavity light-emitting element according to claim 1, wherein
the metal oxide film has a film thickness of 10 nm to 100 nm.
